(19) United States
(12) Patent Application Publication
(10) Pub. No.: US 2004/0197964 A1
(43) Pub. Date: Oct. 7, 2004

(54) Method for fabricating thin film transistor for liquid crystal display device

(76) Inventors: Yu-Chou Lee, Taipei (TW); Tsung-Chi Cheng, Taichung City (TW)

Correspondence Address: PERKINS COIE LLP, PATENT-SEA, P.O. BOX 1247, SEATTLE, WA, 98111-1247, US

(21) Appl. No.: 10/405,316

(22) Filed: Apr. 1, 2003

(51) Int. Cl. H01L 21/00

(52) U.S. Cl. 438/149

(57) ABSTRACT

Material of pixel electrode in thin film transistor (TFT) liquid crystal display (LCD) device is used as source/drain electrodes to combine step of pixel electrode formation and step of source/drain electrodes formation, and a silicide layer is between the source/drain electrodes and a semiconductor layer of the TFT to block light. Lithographic processes are therefore reduced from five times to four times.

### BACKGROUND OF THE INVENTION

1. Field of the Invention

The present invention generally relates to a method for fabricating thin film transistor (TFT) for liquid crystal display device, and more particularly to a method for forming TFT for liquid crystal display (LCD) device by using material of pixel electrode served as material of source/drain.

2. Description of the Prior Art

In conventional manufacturing liquid crystal display device process, lithographic process is a crucial step with high cost and high precise control. Array process with lithographic processes is the most critical step particularly for liquid crystal display device for extremely large numbers of tiny thin film transistors are simultaneously formed on a huge substrate. Hence, decreased numbers of lithographic processes can promote manufacturing yield of liquid crystal display device and reduce capitalized cost. From the array manufacturing process with six lithographic steps in former times to nowadays four lithographic steps, manufacturing cost of reticle and exposure times can be decreased when at least one reticle in lithographic process is reduced, and the necessary high precision steps can be reduced to progress product yield. Therefore, many researches and studies are focused on the reduction of reticles, and published many papers and patents.

Conventional manufacturing array process with five lithographic processes comprises steps of patterning gate electrode, patterning island semiconductor layer, patterning source/drain electrodes, patterning contact window, and patterning pixel electrode. This array process is well-established for several years.

Generally, the four lithographic processes can be applied to the manufacturing array step, because one reticle as well as one exposure process can be applied two etching processes in which two patterns generated by the two etching processes are highly similar. A typical method is to use a reticle with optical correction such that photoresist layer after developed will generate different thickness, and thinner portion of this photoresist layer will be removed at followed etching steps to create masks with different patterns. Therefore, masks with different patterns by using one reticle and one exposure process can be implemented by using multi-etching process to replace original two masks by using two reticles and two lithographic processes.

However, reticles with optical correction will greatly increase manufacturing cost thereof. Using reticles with massive areas is an inevitable way especially for liquid crystal display device manufacturing from fourth generation to fifth generation, even to sixth generation, process. It is very difficult that extremely precise optical corrections are used in such a huge reticle and all optical corrections need to be identical everywhere. Hence, manufacturing yield of reticles is decreased significantly and even impractical.

Therefore, it is an important issue to provide another method for forming TFT array without using above mentioned high cost reticles.

### SUMMARY OF THE INVENTION

In accordance with the present invention, a method for forming thin film transistor for LCD device is provided by using material of pixel electrode served as source/drain electrode to combine the two processes of formation of pixel electrode and source/drain electrode.

It is another object of this invention to use a silicide layer between a semiconductor layer and the source/drain electrodes to reduce resistance therebetween.

It is a further object of this invention to use a silicide layer to block light.

In one embodiment, a method for fabricating thin film transistor for liquid crystal display device is provided with a step of providing a substrate with a gate electrode thereon, a blanket insulating layer on the gate electrode and substrate, and an island semiconductor layer on the insulating layer and over the gate electrode. Then, a silicide layer is formed on the island semiconductor layer. Next, a blanket transparent conductive layer is deposited on the silicide layer and the insulating layer. The transparent conductive layer and said silicide layer are then patterned to etch to form a source region as well as a drain region on the island semiconductor layer and a pixel region on the insulating layer.

Another embodiment of this invention is provided that a method for fabricating thin film transistor for liquid crystal display device comprises a step of forming a gate electrode layer on a substrate and forming a blanket insulating layer on the gate electrode layer and the substrate. Then, a semiconductor layer is blanket deposited on the insulating layer and patterned to form a pattern including a data line, a semiconductor region, a source region, and a drain region. Next, a salicide process is performed to the semiconductor layer to from a silicide layer on the semiconductor layer. A transparent conductive layer is then blanket deposited on the silicide layer and the insulating layer. A lithographic process is performed to form a photoresist layer on the transparent conductive layer. Afterward, the transparent conductive layer is etched by using the photoresist layer as a mask to form a pixel region on the insulating layer, and the silicide layer is also etched by using the photoresist layer as a mask to form a source region and a drain region over the gate electrode layer.

### BRIEF DESCRIPTION OF THE DRAWINGS

The foregoing aspects and many of the attendant advantages of this invention will become more readily appreciated as the same becomes better understood by reference to the following detailed description, when taken in conjunction with the accompanying drawings, wherein:

FIG. 1 illustrates a schematic representation of a gate electrode on a substrate in accordance with this invention;

FIG. 2 illustrates a schematic representation of an insulating layer on the gate electrode and the substrate in accordance with this invention;

FIG. 3 illustrates a schematic representation of an island semiconductor layer on the insulating layer and over the gate electrode in accordance with this invention;

FIG. 4 illustrates a schematic representation of a silicide layer and a transparent conductive layer sequentially formed on the island semiconductor layer in accordance with this invention;

FIG. 5 illustrates a schematic representation of pixel region and source/drain region formed by using a lithographic process and an etching process in accordance with this invention;

FIG. 6 illustrates a schematic representation of a passivation layer covering the thin film transistor element in accordance with this invention;

FIGS. 7A and 7B illustrate schematic representations of a gate electrode and an insulating layer on a substrate in accordance with this invention;

FIGS. 8A and 8B illustrate schematic representations of an amorphous silicon layer formed on the gate electrode and the substrate in accordance with this invention;

FIG. 9 illustrates a schematic representation of a silicide layer formed on the amorphous silicon layer by using salicide process in accordance with this invention;

FIG. 10 illustrates a schematic representation of a blanket transparent conductive layer formed on the silicide layer and the insulating layer in accordance with this invention; and

FIGS. 11A and 11B illustrate schematic representations of pixel region and source/drain region formed by using a lithographic process and an etching process in accordance with this invention.

### DESCRIPTION OF THE PREFERRED EMBODIMENT

Some sample embodiments of the present invention will now be described in greater detail. Nevertheless, it should be recognized that the present invention can be practiced in a wide range of other embodiments besides those explicitly described, and the scope of the present invention is expressly not limited except as specified in the accompanying claims.

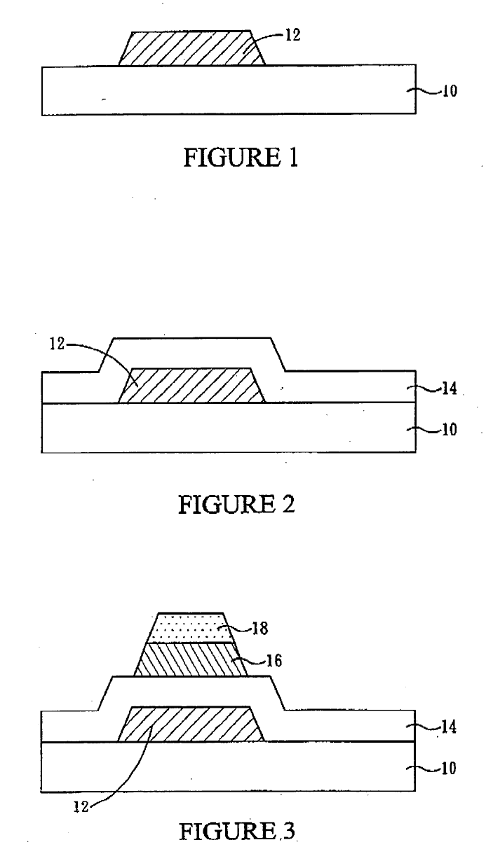

One embodiment of this invention is provided that thin film transistor for liquid crystal display device is fabricated with a step of providing a substrate with a gate electrode thereon, a blanket insulating layer on the gate electrode and substrate, and an island semiconductor layer on the insulating layer and over the gate electrode. The semiconductor includes an amorphous silicon layer and an n+ amorphous silicon layer thereon. Then, a silicide layer is formed on the island semiconductor layer. The silicide layer can be chromium silicide and formed by a salicide process. Next, a blanket transparent conductive layer is deposited on the silicide layer and the insulating layer, wherein the transparent conductive layer can be indium tin oxide. The transparent conductive layer and the silicide layer are then patterned to etch to form a source region as well as a drain region on the island semiconductor layer and a pixel region on the insulating layer. A portion of the n+ amorphous silicon layer is also removed at the step of patterning to etch to form a channel region between the source region and the drain region. Furthermore, a step of forming a blanket passivation layer is performed to cover the source electrode, the drain electrode, and the pixel electrode. The aforementioned steps will be set forth with reference to FIGS. 1-6.

Referring to FIG. 1, a gate electrode layer 12 is formed on a substrate 10. When a back light source is used as light source for liquid crystal display device, the substrate 10 is transparent, such as glass or transparent plastic. When a front light source is used as light source of the display device, the substrate 10 does not necessary be transparent. Material of the gate electrode layer 12 can be metal or any kind of conductive material, such as aluminum or aluminum alloy, molybdenum or molybdenum tungsten alloy, chromium or tantalum. Formation of the gate electrode layer 12 is to deposit a conductive layer by using sputtering method on the substrate 10, and lithographic and etching processes are performed to form gate electrode pattern on the predetermined position. When gate electrode pattern is formed on the substrate 10, gate line (not shown in Figures) is also formed on the substrate 10.

Referring to FIG. 2, a blanket insulating layer 14 is formed on the substrate 10 to cover the gate electrode layer 12. The insulating layer 14, also called gate insulating layer, material of which is silicon nitride, is blanket deposited on the gate electrode layer 12 and substrate 10. The insulating layer 14 serves as gate dielectric layer of the thin film transistor and provides insulate isolation on the other area. Formation of the insulating layer 14 uses popular chemical vapor deposition method.

Referring to FIG. 3, an island semiconductor layer 16, 18 is formed on the insulating layer 14 and over the gate electrode layer 12. The semiconductor layer 16 primarily provides a channel region of the thin film transistor. In thin film transistor liquid crystal display device, channel region is above the gate electrode layer 12, and also named back channel region. The semiconductor layer 16, 18 uses a composite layer within double layers, which is underneath amorphous silicon layer 16 and upper n-doped amorphous silicon layer 18. The underneath amorphous silicon layer 16 provides channel region of the transistor, while the upper n-doped amorphous silicon layer 18 serves as ohmic contact between metal and semiconductor to reduce resistant between metal source/drain and semiconductor layer.

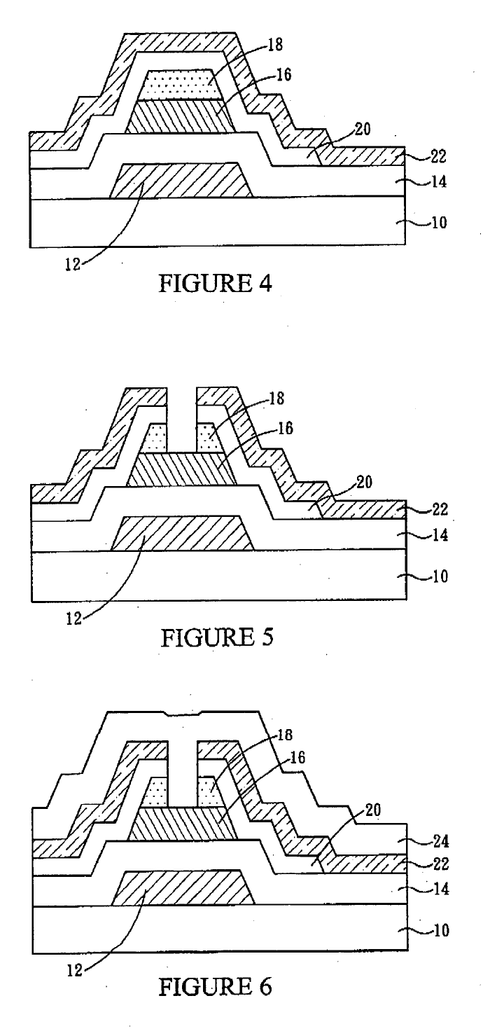

Referring to FIG. 4, a silicide layer 20 and a transparent conductive layer 22 are formed on the semiconductor layer 18 and the insulating layer 14. In this embodiment, the silicide layer 20 is chromium silicide which can be formed by using salicide process. The salicide process, which is self-aligned silicide process, is to deposit a metal layer, which can be chromium or cobalt, on a silicon layer, and an anneal step is performed subsequently to form a silicide layer. The excess or non-reacted metal layer can be removed without using any lithographic process.

The transparent conductive layer 22, which can be indium tin oxide, is served as both pixel electrode and source/drain regions. The pixel electrode is near to the source/drain regions and electrically connected to the drain electrode. The indium tin oxide layer can be formed by using sputtering method with target having tin oxide and indium oxide, or depositing indium oxide with tin-doped.

Referring to FIG. 5, a lithographic process and an etching step are performed to remove a portion of the transparent conductive layer 22, the silicide layer 20, and the n+ amorphous silicon layer 18 to form a pixel electrode on the insulating layer 14, and a source/drain region on the semiconductor layer 18 and over the gate electrode layer 12, and a channel region between the source and drain regions. The transparent conductive layer 22 is etched first by using a photoresist layer (not shown in this Figure) to form the pixel electrode. Then, the silicide layer 20 and the n+ amorphous silicon layer 18 are etched to form the source/drain regions. The aforementioned etching steps can be combined to etch both indium tin oxide layer of the transparent conductive layer and chromium silicide layer by the same etchant and therefore can be performed simultaneously. Therefore, a transistor including a source electrode, a drain electrode, and a gate electrode is formed with the pixel electrode formed simultaneously.

Referring to FIG. 6, a passivation layer 24 is deposited on the transparent conductive layer 22 to cover the pixel electrode and the transistor. The passivation layer 24 can be silicon nitride and formed by chemical vapor deposition method. Then, another lithographic process is performed to form contact hole for the terminals on the peripheral of display panel.

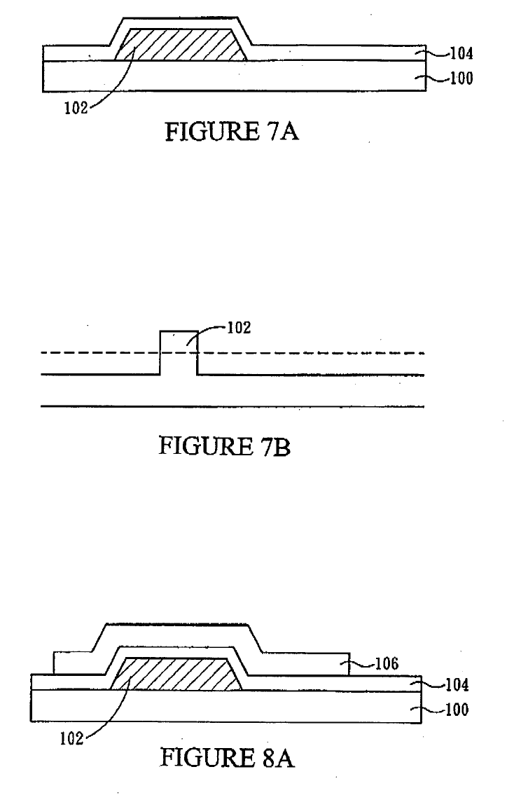

Another embodiment applied to this invention is provided that a method for fabricating thin film transistor for liquid crystal display device comprises a step of forming a gate electrode layer on a substrate and forming a blanket insulating layer on the gate electrode layer and the substrate. Then, a semiconductor layer, which may comprise an amorphous silicon layer and an n+ amorphous silicon layer thereon, is blanket deposited on the insulating layer and patterned to form a pattern including a data line, a semiconductor region, a source region, and a drain region. Next, a salicide process is performed to the semiconductor layer to from a silicide layer on the semiconductor layer. In a preferred embodiment, material of the silicide layer can be chromium silicide. A transparent conductive layer is then blanket deposited on the silicide layer and the insulating layer. In a preferred embodiment, material of the transparent conductive layer can be indium tin oxide. A lithographic process is performed to form a photoresist layer on the transparent conductive layer. Afterward, the transparent conductive layer is etched by using the photoresist layer as a mask to form a pixel region on the insulating layer, and the silicide layer is also etched by using the photoresist layer as a mask to form a source region and a drain region over the gate electrode layer. A portion of the n+ amorphous silicon layer is also removed at the step of etching the silicide layer to form a channel region between the source region and the drain region. Moreover, a step of forming a blanket passivation layer is performed to cover the source electrode, the drain electrode, and the pixel electrode. This embodiment will be set forth next with reference to FIGS. 7 to 11.

Referring to FIG. 7A, a gate electrode 102 is formed on a substrate 100 and a blanket insulating layer 104 is formed on the gate electrode 102 and the substrate 100. Material of the gate electrode layer 102 can be metal or any kind of conductive material, such as aluminum or aluminum alloy, molybdenum or molybdenum tungsten alloy, chromium or tantalum. Formation of the gate electrode layer 102 is to deposit a conductive layer by using sputtering method on the substrate 100, and lithographic and etching processes are performed to form gate electrode pattern on the predetermined position. When gate electrode pattern is formed on the substrate 100, gate line is also formed on the substrate 100 as shown in FIG. 7B of which cross sectional view on dash line is shown in FIG. 7A.

The insulating layer 104, also called gate insulating layer, material of which is silicon nitride, is blanket deposited on the gate electrode layer 102 and substrate 100. The insulating layer 104 serves as gate dielectric layer of the thin film transistor and provides insulate isolation on the other area. Formation of the insulating layer 104 uses popular chemical vapor deposition method.

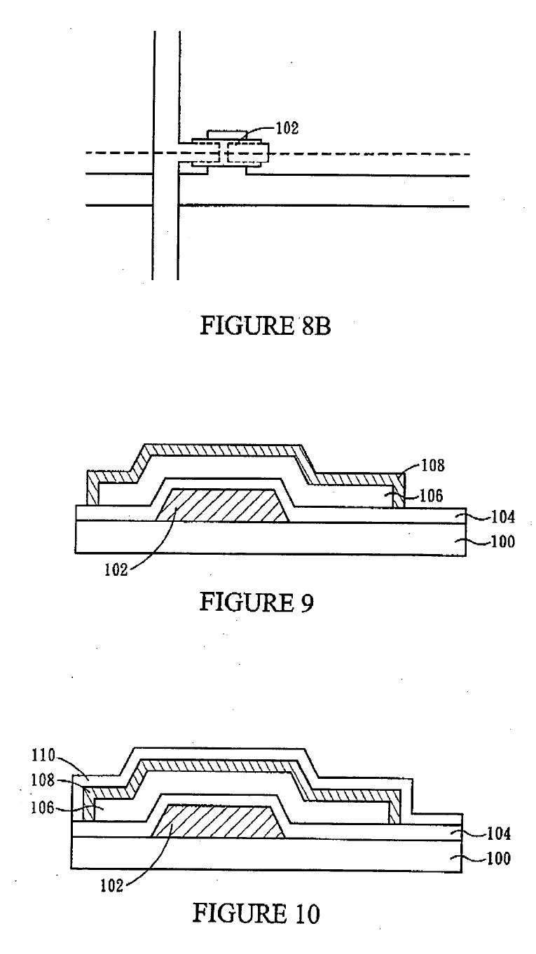

Referring to FIG. 8A, an amorphous silicon layer 106 is formed on the insulating layer 104 and over the gate electrode. Pattern of the amorphous silicon layer 106 comprises island semiconductor layer, source/drain region, and data line, as shown in FIG. 8B of which cross sectional view on dash line is shown in FIG. 8A. The amorphous silicon layer 106 primarily provides a channel region of the thin film transistor. In thin film transistor liquid crystal display device, channel region is above the gate electrode layer 102, and also named back channel region.

Referring to FIG. 9, a silicide layer 108 is formed on the amorphous silicon layer 106. In this embodiment, the silicide layer 108 is chromium silicide which can be formed by using salicide process. The salicide process, which is self-aligned silicide process, is to deposit a metal layer, which can be chromium or cobalt, on a silicon layer, and an anneal step is performed subsequently to form a silicide layer. The excess or non-reacted metal layer can be removed without using any lithographic process. The silicide layer 108 provides ohmic contact between the amorphous silicon layer 106 and the following metal source/drain region. Because the silicide layer 108 is opaque, and provides a good shading ability for the transparent source/drain region in this invention.

Referring to FIG. 10, a blanket transparent conductive layer 110 is formed on the silicide layer 108 and the insulating layer 104. The transparent conductive layer 104, which can be indium tin oxide, is served as both pixel electrode and source/drain regions. The pixel electrode is near to the source/drain regions and electrically connected to the drain electrode. The indium tin oxide layer can be formed by using sputtering method with target having tin oxide and indium oxide, or depositing indium oxide with tin-doped.

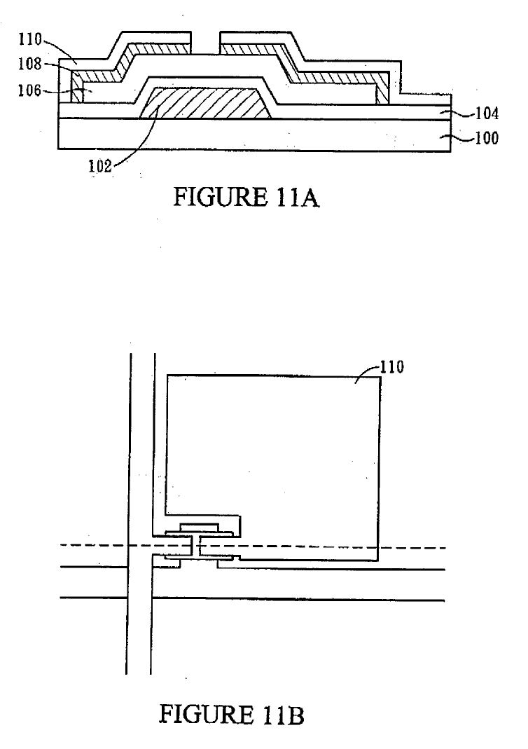

Referring to FIG. 11A and FIG. 11B, a lithographic process and an etching step are performed to remove a portion of the transparent conductive layer 110 and the suicide layer 108 to form a pixel electrode on the insulating layer 104, and a source/drain region on the silicide layer 108 and over the gate electrode layer 102, and a channel region between the source and drain regions. The transparent conductive layer 110 is etched first by using a photoresist layer (not shown in this Figure) to form the pixel electrode. Then, the silicide layer 108 is etched to form the source/drain regions. The aforementioned etching steps can be combined to etch both indium tin oxide layer of the transparent conductive layer and chromium silicide layer by the same etchant and therefore can be performed simultaneously. Therefore, a transistor including a source electrode, a drain electrode, and a gate electrode is formed with the pixel electrode formed simultaneously.

In the second embodiment, silicide layer itself provides good ohmic contact ability between amorphous silicon layer and metal layer.

Thickness of the silicide layer in both embodiments can be ranged from 10 to 200 angstrom. A preferred performance, with lower sheet resistance and higher electric conductivity, for the silicide layer occurs at thickness between 140 to 170 angstrom, and annealing temperature between 200 to 250° C., wherein sheet resistance is between about 1.04E+01 to 2.18E+01 Ω/□ and electric conductivity is between about 1.5E+03 to 3E+03 (1/Ω)-cm.

This invention provides a method for forming TFT array in which the two processes of formation of pixel electrode and source/drain electrode are combined. A silicide layer is used here between the semiconductor layer and the source/drain electrodes to reduce resistance therebetween, and to block light.

Although specific embodiments have been illustrated and described, it will be obvious to those skilled in the art that various modifications may be made without departing from what is intended to be limited solely by the appended claims.

What is claimed is:

1. A method for manufacturing thin film transistor for liquid crystal display device, comprising:
providing a substrate with a gate electrode thereon, a blanket insulating layer on said gate electrode and said substrate, and an island semiconductor layer on said insulating layer and over said gate electrode;
forming a silicide layer on said island semiconductor layer;
blanket depositing a transparent conductive layer on said suicide layer and said insulating layer; and
patterning to etch said transparent conductive layer and said silicide layer to form a source region as well as a drain region on said island semiconductor layer and a pixel region on said insulating layer.

2. The method according to claim 1, wherein said island semiconductor layer comprises an amorphous silicon layer and an n+ amorphous silicon layer thereon.

3. The method according to claim 2, wherein a portion of said n+ amorphous silicon layer is removed at the step of patterning to etch said transparent conductive layer to form a channel region between said source region and said drain region.

4. The method according to claim 1, wherein material of said silicide layer is chromium silicide.

5. The method according to claim 4, wherein said chromium silicide is formed by salicide process.

6. The method according to claim 4, wherein material of said transparent conductive layer is indium tin oxide.

7. The method according to claim 6, wherein said step of patterning to etch said transparent conductive layer utilizes one etchant to etch said transparent conductive layer and said silicide layer.

8. The method according to claim 1, further comprising a step of forming a blanket passivation layer to cover said source region, said drain region, and said pixel region.

9. A method for manufacturing thin film transistor for liquid crystal display device, comprising:
forming a gate electrode on a substrate;
forming a blanket insulating layer on said gate electrode and said substrate;
forming an island semiconductor layer on said insulating layer and over said gate electrode;
forming a chromium silicide layer on said island semiconductor layer;
forming a blanket transparent conductive layer on said chromium silicide layer and said insulating layer;
performing a lithographic process to form a photoresist layer on said transparent conductive layer;
etching said transparent conductive layer by using said photoresist layer as a mask to form a pixel region on said insulating layer; and
etching said chromium silicide layer by using said photoresist layer as a mask to form a source region and a drain region on said island semiconductor layer.

10. The method according to claim 9, wherein said semiconductor layer comprises an amorphous silicon layer and an n+ amorphous silicon layer thereon.

11. The method according to claim 10, wherein a portion of said n+ amorphous silicon layer is removed at the step of etching said silicide layer to form a channel region between said source region and said drain region.

12. The method according to claim 9, wherein said chromium silicide is formed by salicide process.

13. The method according to claim 12, wherein material of said transparent conductive layer is indium tin oxide.

14. The method according to claim 13, wherein said step of etching said transparent conductive layer and said step of etching said chromium silicide layer are performed simultaneously.

15. The method according to claim 14, wherein said step of etching said transparent conductive layer and said step of etching said chromium silicide layer utilize one etchant to etch said transparent conductive layer and said chromium silicide layer.

16. The method according to claim 9, further comprising a step of forming a blanket passivation layer to cover said source electrode, said drain electrode, and said pixel electrode.

17. A method for fabricating thin film transistor for liquid crystal display device, comprising:
forming a gate electrode layer on a substrate;
forming a blanket insulating layer on said gate electrode layer and said substrate;
blanket depositing a semiconductor layer on said insulating layer;
patterning to etch said semiconductor layer to form a pattern including a data line, a semiconductor region, a source region, and a drain region;
performing a salicide process to said semiconductor layer to from a silicide layer on said semiconductor layer;
blanket depositing a transparent conductive layer on said silicide layer and said insulating layer;
performing a lithographic process to form a photoresist layer on said transparent conductive layer;
etching said transparent conductive layer by using said photoresist layer as a mask to form a pixel region on said insulating layer; and
etching said silicide layer by using said photoresist layer as a mask to form a source region and a drain region over said gate electrode layer.

18. The method according to claim 17, wherein said semiconductor layer comprises an amorphous silicon layer and an n+ amorphous silicon layer thereon.

19. The method according to claim 18, wherein a portion of said n+ amorphous silicon layer is removed at the step of etching said silicide layer to form a channel region between said source region and said drain region.

20. The method according to claim 17, wherein material of said silicide layer is chromium silicide.

21. The method according to claim 20, wherein material of said transparent conductive layer is indium tin oxide.

22. The method according to claim 21, wherein said step of etching said transparent conductive layer and said step of etching said chromium silicide layer are performed simultaneously.

23. The method according to claim 17, further comprising a step of forming a blanket passivation layer to cover said source electrode, said drain electrode, and said pixel electrode.
